(19) United States
(12) Patent Application Publication
(10) Pub. No.: US 2024/0128300 A1
(43) Pub. Date: Apr. 18, 2024

(54) SEMICONDUCTOR DEVICE AND ELECTRONIC APPARATUS

(71) Applicant: SONY SEMICONDUCTOR SOLUTIONS CORPORATION, KANAGAWA (JP)

(72) Inventors: TOMOAKI KUDOU, KANAGAWA (JP); YUSUKE OTAKE, KANAGAWA (JP)

(21) Appl. No.: 17/769,556

(22) PCT Filed: Jul. 21, 2020
(86) PCT No.: PCT/JP2020/028199

§ 371 Date: Apr. 15, 2022

(30) Foreign Application Priority Data
Oct. 24, 2019 (JP) 2019-193189

(51) Int. Cl. H01L 27/146; H04N 25/773

(52) U.S. Cl. CPC H01L 27/14643; H01L 27/14605; H01L 27/14629; H01L 27/14636; H01L 27/1464; H04N 25/773; H04N 25/79

(57) ABSTRACT

Provided is a semiconductor device capable of improving quantum efficiency and time resolution. In the semiconductor device, each of a plurality of pixels includes an APD element formed in a semiconductor layer, and a first metal wiring provided on a first surface of the semiconductor layer. The APD element includes: a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and a first contact region of the second conductivity type which is provided in contact with the second electrode region between the first surface of the semiconductor layer and the second electrode region, and of which the contour is located inside a contour of the second electrode region in a plan view. The first metal wiring is electrically connected to the first contact region, and a contour thereof is located between the contour of the second electrode region and the contour of the first contact region in a plan view.

### TECHNICAL FIELD

The present technology (technology according to the present disclosure) relates to a semiconductor device and an electronic apparatus, and particularly, to a technology effective in application to a semiconductor device having an avalanche photodiode (APD) element and an electronic apparatus having the same.

### BACKGROUND ART

As a semiconductor device, a distance image sensor (solid-state image sensor) that measures a distance by a ToF (Time of Flight) method has been attracting attention in recent years. This distance image sensor includes a pixel array portion in which a plurality of pixels are arranged in a matrix. The efficiency of the entire device is determined by the pixel dimensions and the pixel structure.

PTL 1 discloses a pixel having an APD element as a photoelectric conversion element. In this pixel, an APD element is configured in the pixel forming region of a semiconductor layer. The APD element has a photoelectric conversion portion that absorbs light incident on the pixel forming region of the semiconductor layer to generate carriers, and a multiplication portion that avalanche-multiplies the carriers generated by the photoelectric conversion portion.

Further, PTL 1 discloses a technology in which a metal wiring provided in a wiring layer on a semiconductor layer is used as a reflective film and light transmitted through the APD element is reflected by the APD element to improve quantum efficiency.

### CITATION LIST

### Patent Literature

[PTL 1]
JP 2018-088488 A

### SUMMARY

### Technical Problem

By the way, in the APD element, it is desired to shorten the quenching operation (Dead Time) and improve the time resolution. Generally, it is known that the quenching operation is shortened by reducing the RC time constant (product of the resistance component R and the capacitance component C) of the APD element.

However, when the metal wiring on the semiconductor layer is used as a reflective film as in PTL 1, a parasitic capacitance is added between the semiconductor layer and the metal wiring due to the potential difference between the semiconductor layer and the metal wiring, and the time resolution may be reduced.

An object of the present technology is to provide a semiconductor device capable of improving quantum efficiency and time resolution and an electronic apparatus having the same.

### Solution to Problem

A semiconductor device according to an aspect of the present technology includes: a pixel array portion in which a plurality of pixels are arranged in a matrix, each of the plurality of pixels including: an avalanche photodiode element formed in a semiconductor layer; and a first metal wiring provided on a first surface of the semiconductor layer, the avalanche photodiode element including: a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and a first contact region of the second conductivity type which is provided in contact with the second electrode region between the first surface of the semiconductor layer and the second electrode region, and of which the contour is located inside a contour of the second electrode region in a plan view, and the first metal wiring being electrically connected to the first contact region, and a contour thereof being located between the contour of the second electrode region and the contour of the first contact region in a plan view.

A semiconductor device according to another aspect of the present technology includes: a pixel array portion in which a plurality of pixels are arranged in a matrix, each of the plurality of pixels including: an avalanche photodiode element formed in a semiconductor layer; and a first conductive reflective film provided on a first surface of the semiconductor layer, the avalanche photodiode element including: a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and a first contact region of the second conductivity type which is provided in contact with the second electrode region between the first surface of the semiconductor layer and the second electrode region, and of which the contour is located inside a contour of the second electrode region in a plan view, and the first reflective film being electrically connected to the first contact region, and a contour thereof being located between the contour of the second electrode region and the contour of the first contact region in a plan view.

A semiconductor device according to another aspect of the present technology includes: a pixel array portion in which a plurality of pixels are arranged in a matrix, each of the plurality of pixels including: an avalanche photodiode element formed in a semiconductor layer; and an insulating reflective film provided on a first surface of the semiconductor layer, the avalanche photodiode element including: a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and a first contact region of the second conductivity type which is provided in contact with the second electrode region between the first surface of the semiconductor layer and the second electrode region, and of which the contour is located inside a contour of the second electrode region in a plan view, and the reflective film covering an entire surface of the semiconductor layer on the pixel forming region.

An electronic apparatus according to another aspect of the present technology includes the semiconductor device and an optical system that forms an image of image light from a subject on a second surface opposite to the first surface of the semiconductor layer.

### BRIEF DESCRIPTION OF DRAWINGS

FIG. 1 is a chip layout diagram showing a configuration example of a distance image sensor according to a first embodiment of the present technology.

FIG. 2 is a block diagram showing a configuration example of a distance image sensor according to a first embodiment of the present technology.

FIG. 3 is an equivalent circuit diagram showing a configuration example of a pixel.

FIG. 4 is a plan view of a main part showing a configuration example of a pixel.

FIG. 5 is a cross-sectional view of a main part showing a cross-sectional structure taken along line II-II of FIG. 4.

FIG. 6 is an enlarged cross-sectional view of a main part of FIG. 5.

FIG. 7 is a diagram showing an example of an evaluation result of a quenching operation (Dead Time) of a distance image sensor according to an embodiment of the present technology.

FIG. 8 is a cross-sectional view of a main part showing a modified example of the distance image sensor according to the first embodiment of the present technology.

FIG. 9 is a plan view of a main part showing a configuration example of a pixel in a distance image sensor according to a second embodiment of the present technology.

FIG. 10 is a cross-sectional view of a main part showing a cross-sectional structure taken along line III-III of FIG. 9.

FIG. 11 is a plan view of a main part showing a configuration example of a pixel in a distance image sensor according to a third embodiment of the present technology.

FIG. 12 is a cross-sectional view of a main part showing a cross-sectional structure taken along line IV-IV of FIG. 11.

FIG. 13 is a cross-sectional view of a main part showing a configuration example of a pixel in a distance image sensor according to a fourth embodiment of the present technology.

FIG. 14 is a plan view of a main part showing a configuration example of a pixel in a distance image sensor according to a fifth embodiment of the present technology.

FIG. 15 is a cross-sectional view of a main part showing a cross-sectional structure taken along line V-V of FIG. 14.

FIG. 16 is a block diagram showing a configuration example of a distance image apparatus using the sensor chip of the present technology.

### DESCRIPTION OF EMBODIMENTS

Hereinafter, an embodiment of the present technique will be described with reference to drawings. In the descriptions of the drawings to be referred to hereinafter, same or similar portions are denoted by same or similar reference signs. However, it should be noted that the figures are schematic and relationships between thicknesses and planar dimensions, ratios of thicknesses of respective layers, and the like are different from actual ones. Therefore, specific thicknesses and dimensions should be determined by taking the following description into consideration. In addition, it is needless to say that portions having different dimensional relationships and ratios between the figures are included in the figures. The advantageous effects described in the present specification are merely exemplary and are not restrictive, and other advantageous effects may be produced.

In the following embodiment, in the three directions orthogonal to each other in a space, a first direction and a second direction orthogonal to each other in the same plane are set to an X direction and a Y direction, respectively, and a third direction orthogonal to each of the first direction and the second direction is defined as a Z direction.

In the present specification and the accompanying drawings, electrons and holes are dominant carriers in the layer or region marked with “n” and “p”, respectively.

### First Embodiment

In the first embodiment, an example in which the present technology is applied to a back-illuminated distance image sensor as a semiconductor device will be described.

<Structure of Distance Image Sensor>

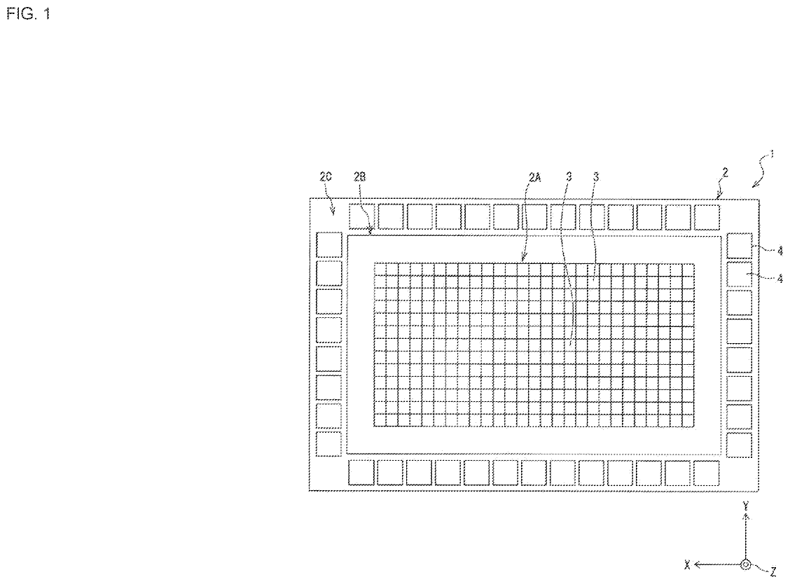

As shown in FIG. 1, a distance image sensor 1 according to the first embodiment of the present technology is mainly composed of a sensor chip 2 having a rectangular two-dimensional planar shape when viewed in a plan view. The sensor chip 2 has a rectangular pixel array portion 2A arranged in the center, a peripheral region 2B arranged outside the pixel array portion 2A so as to surround the pixel array portion 2A, and a pad region 2C arranged outside the peripheral region 2B so as to surround the peripheral region 2B.

The pixel array portion 2A is a light receiving surface that receives light collected by an optical system (not shown). Then, in the pixel array portion 2A, a plurality of pixels 3 are arranged in a matrix in a two-dimensional plane including the X direction and the Y direction.

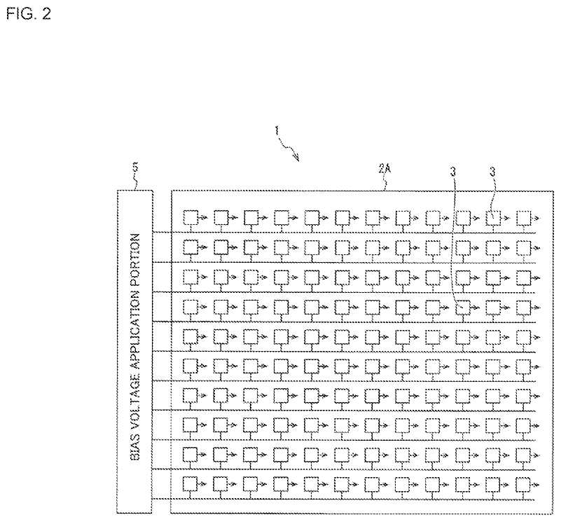

A bias voltage application portion 5 shown in FIG. 2 and other circuit portions are arranged in the peripheral region 2B. The bias voltage application portion 5 applies a bias voltage to each of the plurality of pixels 3 arranged in the pixel array portion 2A.

As shown in FIG. 1, in the pad region 2C, a plurality of electrode pads 4 are arranged along each of the four sides in the two-dimensional plane of the sensor chip 2. The electrode pad 4 is an external terminal used when the sensor chip 2 is electrically connected to an external device (not shown).

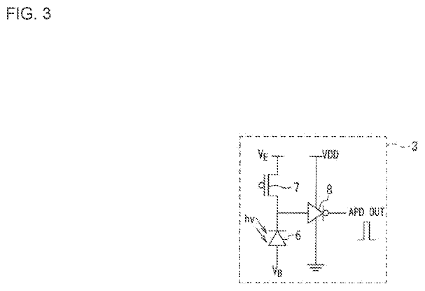

As shown in FIG. 3, each pixel 3 of the plurality of pixels 3 includes an APD (Avalanche photodiode) element 6 as a photoelectric conversion element, for example, a quenching resistance element 7 made of, for example, a p-type MOSFET (Metal Oxide Semiconductor Field Effect Transistor), and an inverter 8 made of, for example, a complementary MOSFET (Complementary MOS).

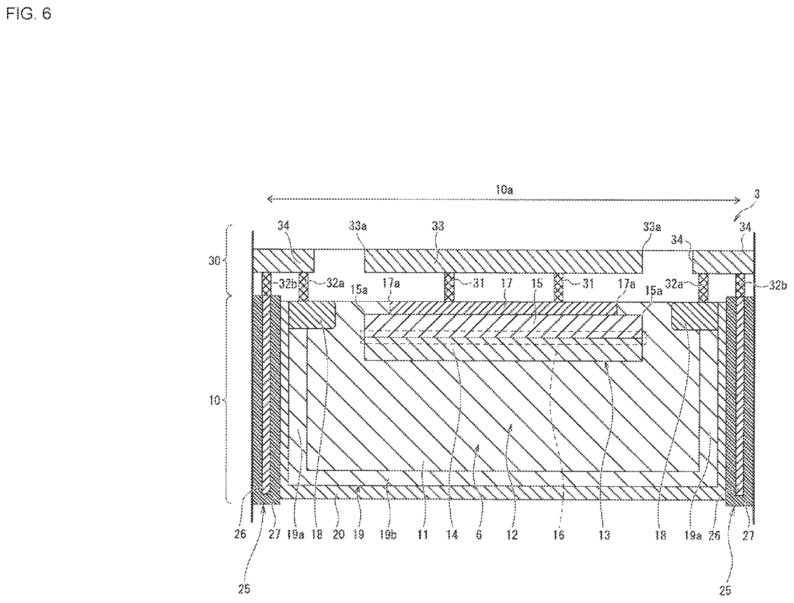

In the APD element 6, the anode is connected to the bias voltage application portion 5 (see FIG. 2), and the cathode is connected to the source terminal of the quenching resistance element 7. A bias voltage VB is applied from the bias voltage application portion 5 to the anode of the APD element 6. The APD element 6 is a photoelectric conversion element capable of forming an avalanche multiplication region 16 (see FIG. 6) with a large negative voltage applied to the cathode and avalanche-multiplying the electrons generated by the incidence of one photon.

The quenching resistance element 7 is connected in series to the APD element 6, the source terminal is connected to the cathode of the APD element 6, and the drain terminal is connected to a power source (not shown). An excitation voltage VE is applied from the power source to the drain terminal of the quenching resistance element 7. When the voltage due to the electrons avalanche-multiplied by the APD element 6 reaches the negative voltage VBD, the quenching resistance element 7 emits the electrons multiplied by the APD element 6 to perform quenching to return the voltage to the initial voltage.

As shown in FIG. 3, the input terminal of the inverter 8 is connected to the cathode of the APD element 6 and the source terminal of the quenching resistance element 7, and the output terminal is connected to a subsequent arithmetic processing unit (not shown). The inverter 8 outputs a light receiving signal based on the electrons multiplied by the APD element 6. More specifically, the inverter 8 shapes the voltage generated by the electrons multiplied by the APD element 6. Then, the inverter 8 outputs a light receiving signal (APD OUT) in which a pulse waveform shown in FIG. 3, for example, starting from the arrival time of one photon, is generated, to the arithmetic processing unit. For example, the arithmetic processing unit performs arithmetic processing for obtaining the distance to the subject based on the timing at which a pulse indicating the arrival time of one photon is generated in each received light signal, and obtains the distance for each pixel 3. Then, based on those distances, a distance image in which the distances to the subject detected by the plurality of pixels 3 are arranged in a plane is generated.

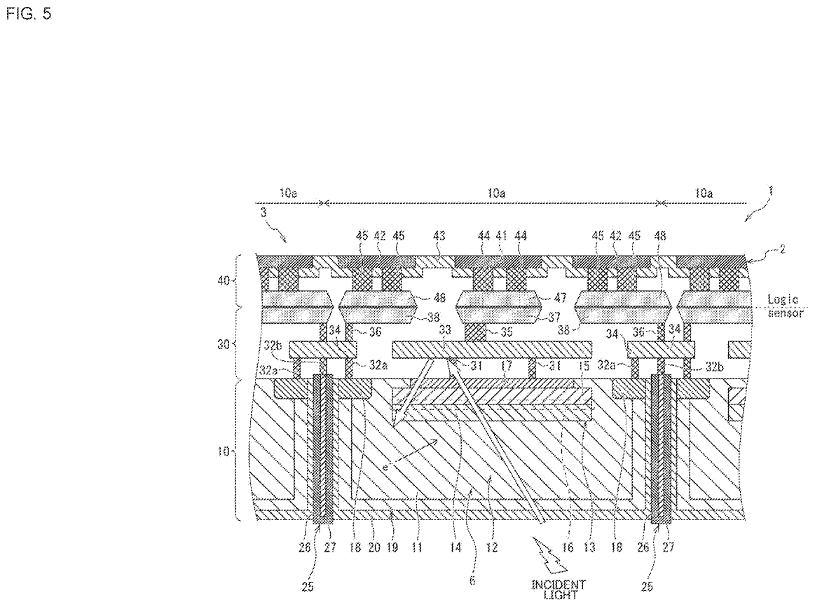

As shown in FIG. 5, the sensor chip 2 has a stacked structure in which a sensor substrate 10 as a semiconductor layer, a sensor-side wiring layer 30, and a logic-side wiring layer 40 are stacked in that order. A logic circuit board (not shown) is stacked on the logic-side wiring layer 40.

For example, the bias voltage application portion 5 shown in FIG. 2, the quenching resistance element 7, the inverter 8, and the like are formed on the logic circuit board. As shown in FIG. 5, the sensor substrate 10 and the logic circuit board are electrically connected by the sensor-side wiring layer 30 and the logic-side wiring layer 40, which are wiring layers. For example, the sensor chip 2 can be manufactured by a manufacturing method of providing the sensor-side wiring layer 30 so as to face the sensor substrate 10, providing the logic-side wiring layer 40 with respect to the logic circuit board, and then bonding the sensor-side wiring layer 30 and the logic-side wiring layer 40 on a bonding surface (the surface shown by the broken line in FIG. 5).

The sensor substrate 10 is formed of, for example, a semiconductor substrate made of a single crystal silicon. In the sensor substrate 10, the concentration of impurities exhibiting p-type (first conductivity type) or n-type (second conductivity type) is controlled, and the APD element 6 is formed for each pixel 3. In FIG. 5, the surface facing the lower side of the sensor substrate 10 is a light receiving surface that receives light, and the sensor-side wiring layer 30 is tacked on the surface opposite to the light receiving surface (the surface facing the upper side in FIG. 5). An on-chip lens (not shown) is provided for each pixel 3 on the light receiving surface of the sensor substrate 10.

Here, the light receiving surface of the sensor substrate 10 may be referred to as a second surface or a light incident surface, and the surface opposite to the light receiving surface may be referred to as a first surface or a principal surface. The first surface side of the sensor substrate 10 may be referred to as an upper portion, and the second surface side may be referred to as a lower portion. The light receiving surface of the sensor substrate 10 may be referred to as a back surface with respect to the principal surface.

In the sensor-side wiring layer 30 and the logic-side wiring layer 40, wirings for supplying a voltage applied from the bias voltage application portion 5 to the APD element 6 and wirings for extracting electrons generated by the APD element 6 from the sensor substrate 10 are formed.

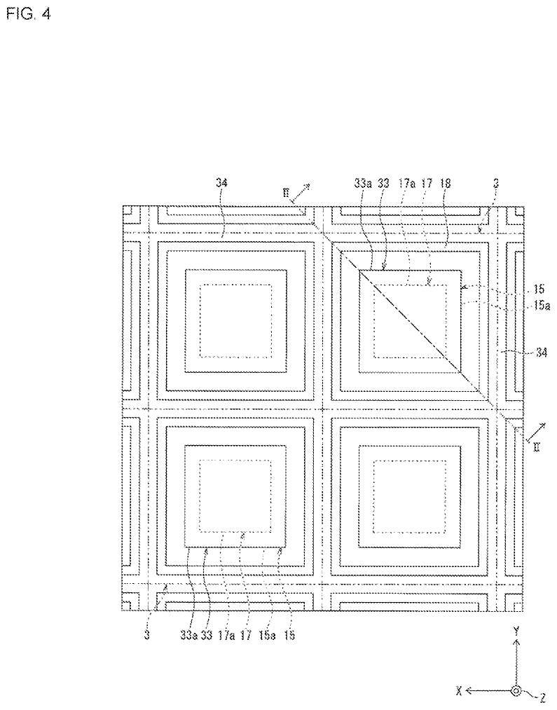

As shown in FIGS. 4 and 5, the pixel 3 includes a pixel forming region 10a of the sensor substrate 10 and an inter-pixel separation region 25 for partitioning the pixel forming region 10a. The pixel forming region 10a has a square planar pattern when viewed in a plan view toward the first surface of the sensor substrate 10. A plurality of pixel forming regions 10a are arranged via the inter-pixel separation region 25 in the respective directions of the X direction and the Y direction orthogonal to each other. The pixel forming region 10a is electrically and optically separated from the adjacent pixel forming regions 10a by the inter-pixel separation region 25. The APD element 6 is formed in each pixel forming regions 10a of the plurality of pixel forming regions 10a.

The inter-pixel separation region 25 has a three-layer structure in which both sides of the metal film 26 are sandwiched by the insulating films 27 in a direction orthogonal to the thickness direction (Z direction) of the sensor substrate 10. The inter-pixel separation region 25 extends from the first surface to the second surface of the sensor substrate 10. The metal film 26 is formed of a metal film that reflects light, for example, a tungsten (W) film. The insulating film 27 is formed of an insulating film, for example, a silicon oxide (SiO₂) film.

Although not shown in detail, the inter-pixel separation region 25 corresponding to one pixel 3 has a square annular planar pattern when viewed in a plan view toward the first surface of the sensor substrate 10. The inter-pixel separation region 25 corresponding to the pixel array portion 2A has a composite planar pattern having a grid-like planar pattern in a square annular planar pattern.

As described above, each pixel 3 of the plurality of pixels 3 includes the APD element 6. Then, as shown in FIGS. 5 and 6, the pixel 3 further includes a first metal wiring 33 and a second metal wiring 34 provided in the sensor-side wiring layer 30 as a wiring layer on the first surface of the sensor substrate 10. The first metal wiring 33 and the second metal wiring 34 are formed of a metal film having excellent conductivity and excellent light reflectivity, for example, a copper (Cu) film or a copper alloy film mainly composed of copper.

As shown in FIGS. 5 and 6, the APD element 6 has a p-type (first conductivity type) well region 11 provided in the pixel forming region 10a of the sensor substrate 10 from the first surface to the second surface of the sensor substrate 10 and a light absorbing portion 12 and a multiplication portion 13 sequentially provided in the p-type well region 11 from the second surface side (lower surface side in FIGS. 5 and 6) to the first surface side (upper surface side in FIGS. 5 and 6) of the sensor substrate 10.

The APD element 6 has an n-type first contact region 17 provided in the pixel forming region 10a of the sensor substrate 10 by being electrically connected to an n-type second electrode region 15 described later, and a p-type second contact region 18 provided in the pixel forming region 10a of the sensor substrate 10 by being electrically connected to a p-type first electrode region 14 described later. The APD element 6 has a p-type charge storage region 19 and a p-type pinning region 20 provided by being electrically connected to the p-type well region 11 and the p-type second contact region 18.

The light absorbing portion 12 is a photoelectric conversion portion that is mainly composed of the p-type well region 11 and absorbs light incident from a second surface (light incident surface) of the sensor substrate 10 to generate electrons (carriers). Then, the light absorbing portion 12 transfers the electrons generated by the photoelectric conversion to the multiplication portion 13 by an electric field. The p-type well region 11 is composed of a p-type semiconductor region having the lowest impurity concentration among the semiconductor regions constituting the APD element 6.

The multiplication portion 13 avalanche-multiplies the electrons transferred from the light absorbing portion 12. The multiplication portion 13 includes a p-type first electrode region 14 provided on the first surface side of the sensor substrate 10 and an n-type second electrode region 15 provided at a position shallower than the p-type first electrode region 14 from the first surface of the sensor substrate 10 to form a pn junction with the p-type first electrode region 14, and an avalanche multiplication region 16 is formed at an interface of the pn junction.

As shown in FIGS. 5 and 6, the p-type first electrode region 14 and the n-type second electrode region 15 forming the pn junction are sequentially arranged in the p-type well region 11 from the second surface of the sensor substrate 10 to the first surface. In this first embodiment, the n-type second electrode region 15 is provided apart from the first surface of the sensor substrate 10 in the depth direction. As shown in FIG. 4, the n-type second electrode region 15 has a square planar pattern when viewed in a plan view. Similarly, the p-type first electrode region 14 also has a square planar pattern when viewed in a plan view, and has a planar size substantially the same as that of the n-type second electrode region 15. That is, the multiplication portion 13 including the p-type first electrode region 14 and the n-type second electrode region 15 has a square planar pattern when viewed in a plan view. The p-type first electrode region 14 is composed of a p-type semiconductor region having a higher impurity concentration than the p-type well region 11, and the n-type second electrode region 15 is composed of an n-type semiconductor region having a higher impurity concentration than the p-type well region 11.

The avalanche multiplication region 16 is a high electric field region (depletion layer) formed at the interface of the pn junction between the p-type first electrode region 14 and the n-type second electrode region 15 by a large negative voltage applied to the n-type second electrode region 15 and multiplies the electrons (e⁻) generated by one photon incident on the APD element 6.

As shown in FIG. 6, the p-type charge storage region 19 is provided along the wall surface of the inter-pixel separation region 25. Then, in this first embodiment, the p-type charge storage region 19 is provided along the second surface of the sensor substrate 10. That is, the p-type charge storage region 19 is formed so that the p-type well region 11 is surrounded by a first portion 19a in contact with the side surface of the p-type well region 11 and a second portion 19b in contact with the bottom surface of the p-type well region 11.

The p-type charge storage region 19 is composed of a p-type semiconductor region having a higher impurity concentration than the p-type well region 11 and the p-type first electrode region 14, and stores holes as carriers. The p-type charge storage region 19 is electrically connected to the p-type second contact region 18 that functions as an anode, and enables bias adjustment. In this way, the hole concentration in the p-type charge storage region 19 is strengthened and the pinning is strengthened, so that, for example, the generation of dark current can be suppressed.

The p-type pinning region 20 is provided between the p-type charge storage region 19 and the inter-pixel separation region 25, and between the p-type charge storage region 19 and the second surface of the sensor substrate 10. The p-type pinning region 20 suppresses the generation of, for example, a dark current, similarly to the p-type charge storage region 19. The p-type pinning region 20 is composed of a p-type semiconductor region having a higher impurity concentration than the p-type well region 11 and the p-type first electrode region 14.

As shown in FIGS. 6 and 4, the p-type second contact region 18 is provided so as to surround the outer periphery of the well region 11 in the surface layer portion on the first surface side of the sensor substrate 10 and overlap with the first portion 12a of the p-type charge storage region 19. That is, the p-type second contact region 18 has a square annular planar pattern in a plan view, and is in contact with and electrically connected to the first portion 12a of the p-type charge storage region 19 over the entire circumference of the annular planar pattern. The p-type second contact region 18 reduces the ohmic contact resistance with a contact electrode 32a described later and functions as an anode. The p-type second contact region 18 is composed of a p-type semiconductor region having a higher impurity concentration than the p-type first electrode region 14 and the p-type charge storage region 19.

As shown in FIGS. 6 and 4, the n-type first contact region 17 is provided in content with the n-type second electrode region 15 between the first surface of the sensor substrate 10 and the n-type second electrode region 15, and a contour 17a in a plan view is located inside a contour 15a of the n-type second electrode region 15. In this first embodiment, the n-type first contact region 17 is provided on the n-type second electrode region 15 with a bottom portion being in contact with the upper portion of the n-type second electrode region 15, but is not limited thereto. The n-type first contact region 17 has a square planar pattern when viewed in a plan view, for example.

The n-type first contact region 17 is composed of an n-type semiconductor region having a higher impurity concentration than the n-type second electrode region 15, and reduces the ohmic contact resistance with the contact electrode 31 described later and functions as a cathode.

As shown in FIG. 5, the sensor-side wiring layer 30 is provided with contact electrodes 31, 32a, and 32b, a first metal wiring 33, a second metal wiring 34, contact electrodes 35 and 36, and metal pads 37 and 38.

The contact electrode 31 electrically connects the n-type first contact region 17 and the first metal wiring 33, and the contact electrode 32a electrically connects the p-type second contact region 18 and the second metal wiring 34. The contact electrode 32b electrically connects the metal film 26 of the inter-pixel separation region 25 and the second metal wiring 34.

As shown in FIGS. 5 and 6, the first metal wiring 33 is provided on the first surface of the pixel forming region 10a of the sensor substrate 10 so as to cover at least the n-type first contact region 17, and a planar shape when viewed in a plan view is formed in a square shape according to the planar shape of the n-type second electrode region 15. Then, as shown in FIGS. 6 and 4, a contour 33a of the first metal wiring 33 is located between the contour 15a of the n-type second electrode region 15 and the contour 17a of the n-type first contact region 17 in a plan view. In this first embodiment, the contour 33a of the first metal wiring 33 is flush with the contour 15a of the n-type second electrode region 15, for example. In other words, the outer peripheral edge of the first metal wiring 33 is aligned with the outer peripheral edge of the n-type second electrode region 15 when viewed in a plan view.

As shown by the blank arrow in FIG. 5, the first metal wiring 33 reflects the light incident from the second surface of the pixel forming region 10a of the sensor substrate 10 and having passed through the APD element 6 to the APD element 6.

As shown in FIGS. 4 to 6, the second metal wiring 34 is provided so as to surround the outer periphery of the first metal wiring 33 and overlap with the p-type second contact region 18 and the inter-pixel separation region 25. As shown in FIG. 4, the second metal wiring 34 corresponding to one pixel 3 has a square annular planar pattern in a plan view. Further, although not shown in detail, the second metal wiring 34 corresponding to the pixel array portion 2A has a composite planar pattern having a grid-like planar pattern in a square annular pattern in a plan view. The second metal wiring 34 is formed to be wider than the width of the inter-pixel separation region 25, and is electrically connected to the p-type second contact regions 18 of the pixels 3 adjacent to each other via the inter-pixel separation region 25.

As shown in FIG. 5, the contact electrode 35 electrically connects the first metal wiring 33 and the metal pad 37, and the contact electrode 36 electrically connects the second metal wiring 34 and the metal pad 38.

The metal pads 37 and 38 are electrically and mechanically connected to metal pads 47 and 48 provided in the logic-side wiring layer 40 by metal-to-metal bonding, respectively.

As shown in FIG. 5, the logic-side wiring layer 40 is provided with electrode pads 41 and 42, an insulating layer 43, contact electrodes 44 and 45, and the above-mentioned metal pads 47 and 48.

The electrode pads 41 and 42 are connected to a logic circuit board (not shown), and the insulating layer 43 insulates the electrode pad 41 and the electrode pad 42 from each other.

The contact electrode 44 electrically connects the electrode pad 41 and the metal pad 47, and the contact electrode 45 electrically connects the electrode pad 42 and the metal pad 48.

The metal pad 37 is bonded to the metal pad 47, and the metal pad 38 is bonded to the metal pad 48.

With such a wiring structure, for example, the electrode pad 41 is electrically connected to the n-type second electrode region 15 via the contact electrode 44, the metal pad 47, the metal pad 37, the contact electrode 35, the first metal wiring 33, the contact electrode 31, and the n-type first contact region 17. Therefore, in the pixel 3, a large negative voltage applied to the n-type second electrode region 15 can be supplied from the logic circuit board to the electrode pad 41.

The electrode pad 42 is electrically connected to the p-type second contact region 18 via the contact electrode 45, the metal pad 48, the metal pad 38, the contact electrode 36, the second metal wiring 34, and the contact electrode 32a. Therefore, in the pixel 3, the anode of the APD element 6 electrically connected to the p-type charge storage region 19 is electrically connected to the electrode pad 42, so that the bias for the p-type charge storage region 19 can be adjusted via the electrode pad 42.

The electrode pad 42 is electrically connected to the metal film 26 of the inter-pixel separation region 25 via the contact electrode 45, the metal pad 48, the metal pad 38, the contact electrode 36, the second metal wiring 34, and the contact electrode 32b. Therefore, in the pixel 3, the bias voltage supplied from the logic circuit board to the electrode pad 42 can be applied to the metal film 26.

### Effect of First Embodiment

Next, the main effects of this first embodiment will be described.

In the distance image sensor 1 according to the first embodiment, as described above, the contour 33a of the first metal wiring 33 of the pixel 3 is located between the contour 15a of the n-type second electrode region 15 and the contour 17a of the n-type first contact region 17 in a plan view. Therefore, according to the distance image sensor 1 of the first embodiment, since the light incident from the second surface of the sensor substrate 10 and having passed through the APD element 6 is reflected by the first metal wiring 33 and returns to the APD element 6, the quantum efficiency of the APD element 6 can be improved by the reflection effect of the first metal wiring 33. Since the first metal wiring 33 basically does not protrude outside the n-type second electrode region 15, it is possible to reduce or eliminate the parasitic capacitance added between the sensor substrate 10 and the first metal wiring 33 due to the potential difference between the p-type well region 11 of the sensor substrate 10 and the first metal wiring 33 and to reduce the overall cathode capacitance. As a result, the quenching operation (Dead Time) of the APD element 6 can be shortened, and the time resolution can be improved. That is, according to the distance image sensor 1 of the first embodiment 1, it is possible to improve the quantum efficiency and the time resolution.

In the distance image sensor 1 according to the first embodiment, the inter-pixel separation region 25 includes the metal film 26 as described above. Therefore, according to the distance image sensor 1 of the first embodiment, the generation of optical crosstalk between the pixels 3 can be suppressed by the light reflection effect of the first metal wiring 33 and the metal film 26, and the sensitivity of the APD element 6 can be improved.

As described above, in the pixel 3 of the distance image sensor 1 according to the first embodiment, the side surface and the bottom surface of the p-type well region 11 are surrounded by the p-type charge storage region 19, and the p-type charge storage region 19 is electrically connected to the anode of the APD element 6, the bias can be adjusted. In the pixel 3, it is possible to form an electric field that assists the carriers in the avalanche multiplication region 16 by applying a bias voltage to the metal film 26 in the inter-pixel separation region 25.

Here, the larger the planar area of the first metal wiring, the greater the reflection efficiency of returning the light incident from the second surface of the sensor substrate 10 and having passed through the APD element 6 to the APD element 6 by the reflection of the first metal wiring 33. Therefore, when the distance from the contour 15a of the n-type second electrode region 15 to the contour 17a of the n-type first contact region 17 is 1, the contour 33a of the first metal wiring 33 is preferably located at a position of 50% or more outward from the contour 17a of the n-type first contact region 17, and more preferably, at a position of 80% or more outward from the contour 17a of the n-type first contact region 17. Further, it is most preferable that the contour 33a of the first metal wiring 33 and the contour 17a of the n-type second electrode region 15 are flush with each other as in the first embodiment. However, considering manufacturing variations such as mask misalignment, the position of the contour 33a of the first metal wiring 33 is preferably in the range of 5% to 10% inward from the contour 15a of the n-type second electrode region 15. In short, it is preferable to make the planar size of the first metal wiring 33 as large as possible in the projection region of the n-type second electrode region 15.

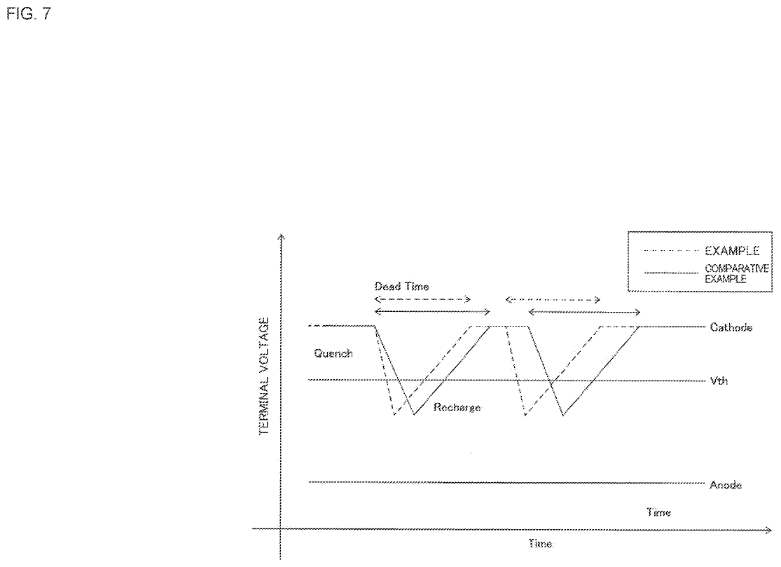

FIG. 7 shows an example of the measurement results of the quenching operation (Dead Time) of the distance image sensor 1 according to the first embodiment as Example and the conventional distance image sensor as Comparative Example. As shown in FIG. 7, in Example, the quenching operation is clearly shorter than that in Comparative Example. Therefore, it was confirmed that the distance image sensor 1 according to the first embodiment is effective in improving the time resolution.

### Modified Example

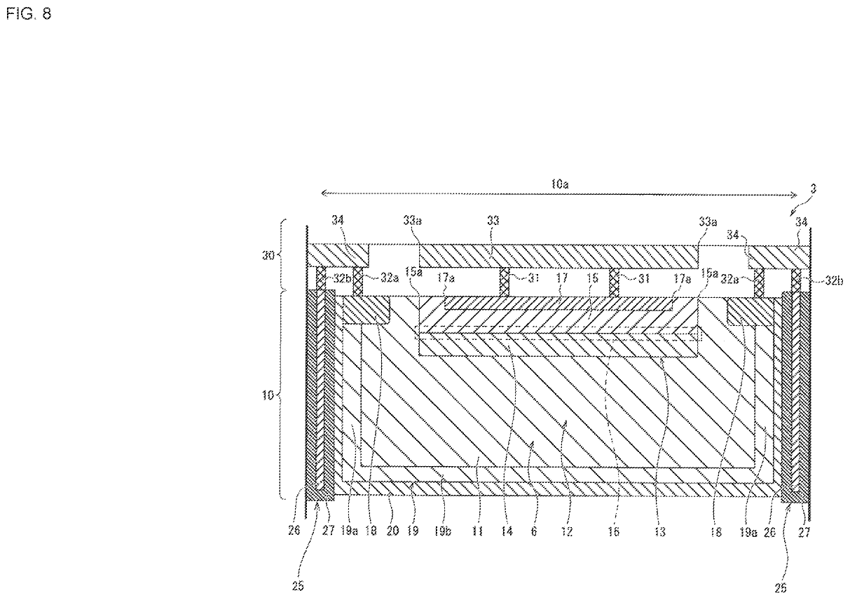

In the above-described first embodiment, a case where the n-type first contact region 17 is arranged on the n-type second electrode region 15 so that the lower portion of the n-type first contact region 17 is in contact with the upper portion of the n-type second electrode region 15 has been described. However, the present technology is not limited to the arrangement of the n-type first contact region 17 in the first embodiment. For example, as shown in FIG. 8, the n-type first contact region 17 may be arranged in the n-type second electrode region 15.

### Second Embodiment

A distance image sensor 1A according to the second embodiment of the present technology has basically the same configuration as the distance image sensor 1 according to the first embodiment described above, and the configuration of the second metal wiring 34 of the pixel 3 is different from that of the first embodiment described above. Other configurations are the same as those of the first embodiment described above.

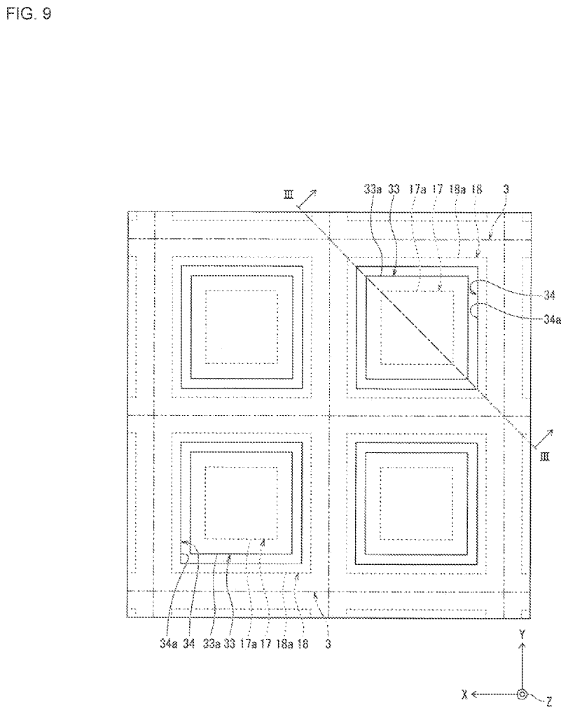

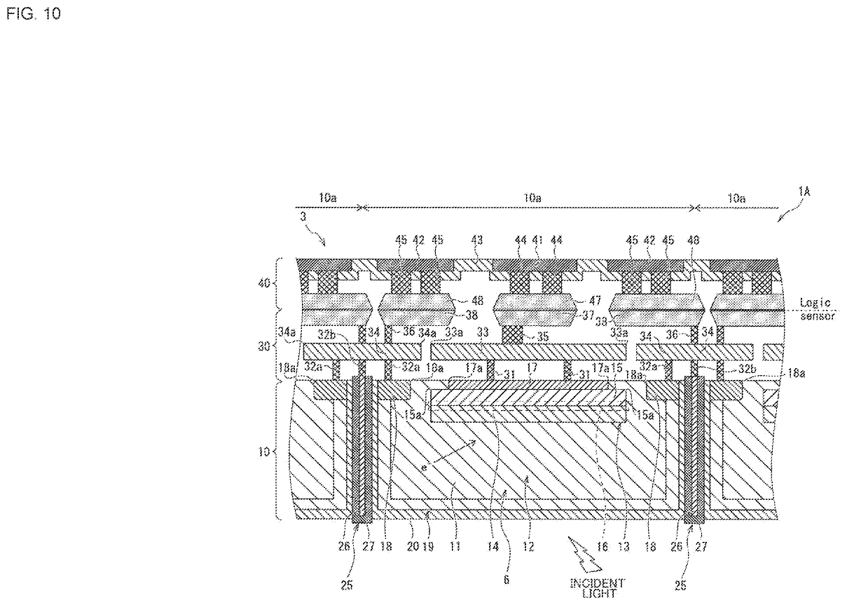

That is, as shown in FIGS. 9 and 10, the contour 34a of the second metal wiring 34 of the second embodiment is located between the contour 18a of the second contact region 18 and the contour 15a of the n-type second electrode region 15 in a plan view. Therefore, according to the distance image sensor 1A of the second embodiment, since the light incident from the second surface of the sensor substrate 10 and having passed through the APD element 6 is reflected by the second metal wiring 34 and returns to the APD element 6, the quantum efficiency of the APD element 6 can be further improved as compared with the first embodiment by the reflection effect of the second metal wiring 34. Since the second metal wiring 34 basically does not overlap with the n-type second electrode region 15, a parasitic capacitance is not added between the n-type second electrode region 15 and the second metal wiring 34 due to the potential difference between the n-type second electrode region 15 and the second metal wiring 34. Therefore, according to the distance image sensor 1A of the first embodiment 1, it is possible to further improve the quantum efficiency and the time resolution as compared with the distance image sensor 1 according to the first embodiment.

In this second embodiment, as in the first embodiment described above, a case where the n-type first contact region 17 is arranged on the n-type second electrode region 15 so that the lower portion of the n-type first contact region 17 is in contact with the upper portion of the n-type second electrode region 15 has been described. However, the present technology is not limited to the arrangement of the n-type first contact region 17 in the second embodiment. For example, as described with reference to FIG. 8, the n-type first contact region 17 may be arranged in the n-type second electrode region 15.

### Third Embodiment

The distance image sensor 1B according to the third embodiment of the present technology has basically the same configuration as the distance image sensor 1 according to the first embodiment described above, and the configuration of the pixel 3 is different from that of the first embodiment described above. Other configurations are the same as those in the first embodiment described above.

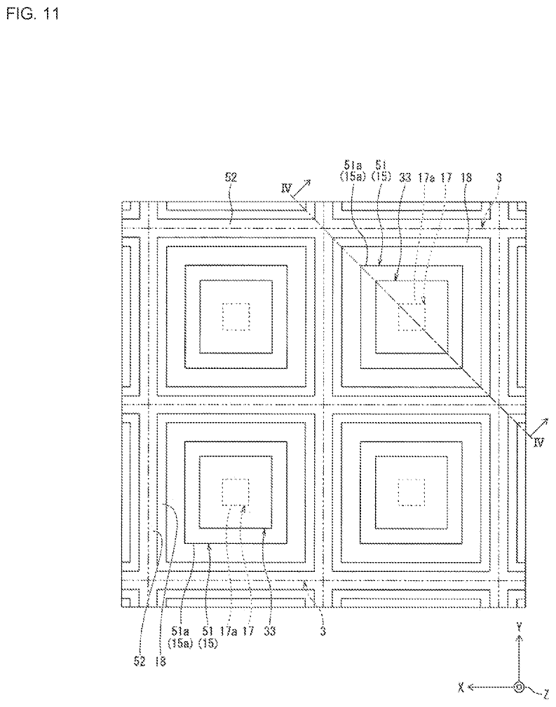

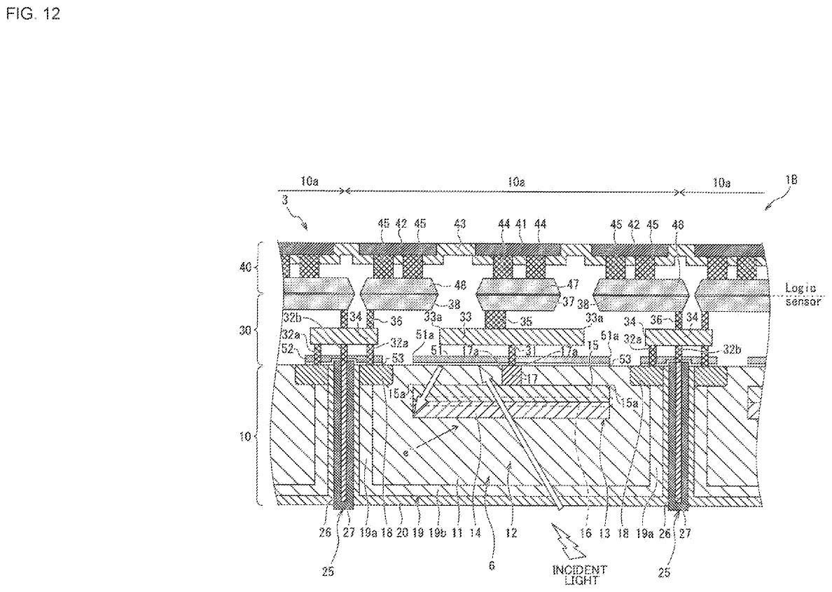

That is, as shown in FIGS. 11 and 12, the pixel 3 of the third embodiment further includes a first reflective film 51 and a second reflective film 52. The first reflective film 51 and the second reflective film 52 is formed of a conductive film having a higher reflectance than the insulating film provided on the sensor-side wiring layer 30, for example, such as a tungsten film or a polycrystalline silicon film into which impurities have been introduced. The first reflective film 51 is arranged closer to the sensor substrate 10 than the first metal wiring 33 so as to overlap with the first metal wiring 33. The second reflective film 52 is arranged closer to the sensor substrate 10 than the second metal wiring 34 so as to overlap with the second metal wiring 34.

The first reflective film 51 is provided on the first surface of the pixel forming region 10a of the sensor substrate 10 via the insulating film 53, and is electrically separated from the p-type well region 11. The first reflective film 51 is provided on the first surface of the pixel forming region 10a of the sensor substrate 10 so as to cover at least the n-type first contact region 17, and the planar shape when viewed in a plan view is formed in a square shape according to the planar shape of the n-type second electrode region 15. The contour 51a of the first reflective film 51 is located between the contour 15a of the n-type second electrode region 15 and the contour 17a of the n-type first contact region 17 in a plan view. In this third embodiment, the contour 51a of the first reflective film 51 is flush with the contour 15a of the n-type second electrode region 15, for example, like the first metal wiring 33 in the first embodiment described above. In other words, the outer peripheral edge of the first reflective film 51 is aligned with the outer peripheral edge of the n-type second electrode region 15 when viewed in a plan view. The first metal wiring 33 in the third embodiment has a planar size smaller than the planar size of the first reflective film 51.

As shown by the blank arrow in FIG. 12, the first reflective film 51 reflects the light incident from the second surface of the pixel forming region 10a of the sensor substrate 10 and having passed through the APD element 6 to the APD element 6.

The second reflective film 52 is provided on the p-type second contact region 18 and the inter-pixel separation region 25 via the insulating film 53. The second reflective film 52 is provided so as to surround the outer periphery of the first reflective film 51 and overlap with the p-type second contact region 18 and the inter-pixel separation region 25. As shown in FIG. 11, the second reflective film 52 corresponding to one pixel 3 has a square annular planar pattern in a plan view. Further, although not shown in detail, the second reflective film 52 corresponding to the pixel array portion 2A has a composite planar pattern having a grid-like planar pattern in the square annular pattern in a plan view. The second reflective film 52 is formed to be wider than the width of the inter-pixel separation region 25, and is provided over the second contact regions 18 of the pixels 3 adjacent to each other via the inter-pixel separation region 25. In this third embodiment, the contact electrode 31 penetrates the first reflective film 51 and the insulating film 53 and is electrically connected to the n-type first contact region 17. The contact electrode 32a penetrates the second reflective film 52 and the insulating film 53 and is electrically connected to the p-type second contact region 18. The contact electrode 32b penetrates the second reflective film 52 and the insulating film 53 and is electrically connected to the metal film 26 of the inter-pixel separation region 25.

In the distance image sensor 1B according to the third embodiment, as described above, the contour 51a of the first reflective film 51 of the pixel 3 is located between the contour 15a of the n-type second electrode region 15 and the contour 17a of the n-type first contact region 17 in a plan view. Therefore, according to the distance image sensor 1B of the third embodiment, since the light incident from the second surface of the sensor substrate 10 and having passed through the APD element 6 is reflected by the first reflective film 51 and returns to the APD element 6, the quantum efficiency of the APD element 6 can be improved by the reflection effect of the first reflective film 51. Since the first reflective film 51 basically does not protrude outside the n-type second electrode region 15, it is possible to reduce or eliminate the parasitic capacitance added between the sensor substrate 10 and the first reflective film 51 due to the potential difference between the p-type well region 11 of the sensor substrate 10 and the first reflective film 51 and to reduce the overall cathode capacitance. As a result, the quenching operation (Dead Time) of the APD element 6 can be shortened, and the time resolution can be improved. That is, in the distance image sensor 1B according to the third embodiment, it is also possible to improve the quantum efficiency and the time resolution.

In this third embodiment, as in the first embodiment described above, a case where the n-type first contact region 17 is arranged on the n-type second electrode region 15 so that the lower portion of the n-type first contact region 17 is in contact with the upper portion of the n-type second electrode region 15 has been described. However, the present technology is not limited thereto, and as in the above-described modified example, as illustrated in FIG. 8, the n-type first contact region 17 may be arranged in the n-type second electrode region 15.

### Fourth Embodiment

The distance image sensor 1C according to the fourth embodiment of the present technology has basically the same configuration as that of the third embodiment described above, and the configuration of the second reflective film 52 of the pixel 3 is different from that of the third embodiment described above. Other configurations are the same as those in the third embodiment described above.

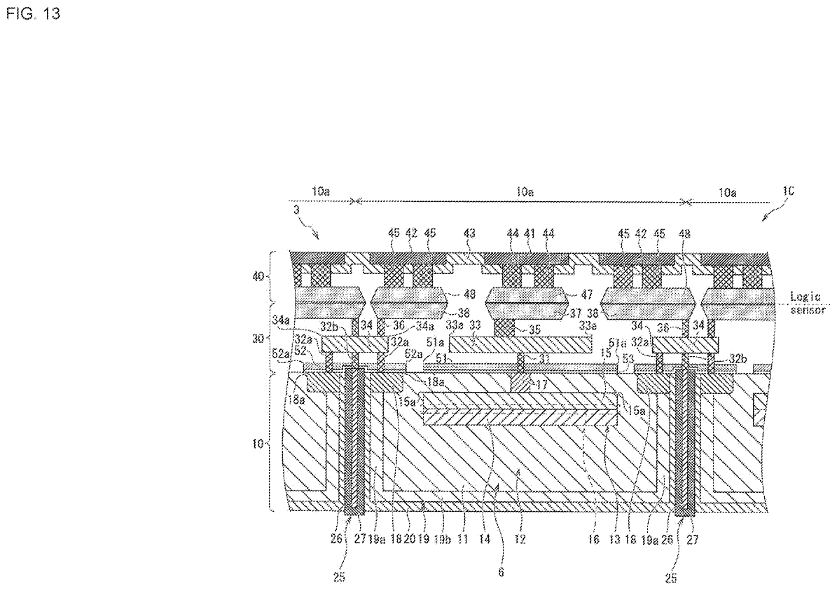

That is, as shown in FIG. 13, the contour 52a of the second reflective film 52 of the fourth embodiment is located between the contour 18a of the p-type second contact region 18 and the contour 15a of the n-type second electrode region 15 in a plan view. Therefore, according to the distance image sensor 1C of the fourth embodiment, as in the distance image sensor 1A of the second embodiment described above, since the light incident from the second surface of the sensor substrate 10 and having passed through the APD element 6 is reflected by the second reflective film 52 and returns to the APD element 6, the quantum efficiency of the APD element 6 can be further improved by the reflection effect of the second reflective film 52 as compared with the third embodiment. Since the second reflective film 52 basically does not overlap with the n-type second electrode region 15, a parasitic capacitance is not added between the n-type second electrode region 15 and the second reflective film 52 due to the potential difference between the n-type second electrode region 15 and the second reflective film 52. Therefore, in the distance image sensor 1C according to the fourth embodiment 1, it is also possible to further improve the quantum efficiency and the time resolution.

In this fourth embodiment, similarly to the above-described modified example, with reference to FIG. 8, the n-type first contact region 17 may be arranged in the n-type second electrode region 15.

### Fifth Embodiment

The distance image sensor 1D according to the fifth embodiment of the present technology has basically the same configuration as the distance image sensor 1B according to the third embodiment described above, and the configuration of the pixel 3 is different from that of the third embodiment described above. Other configurations are the same as those in the third embodiment described above.

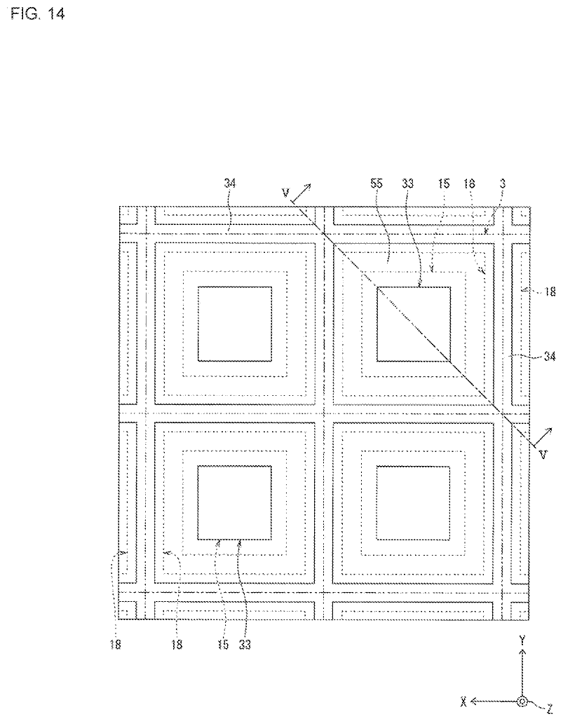

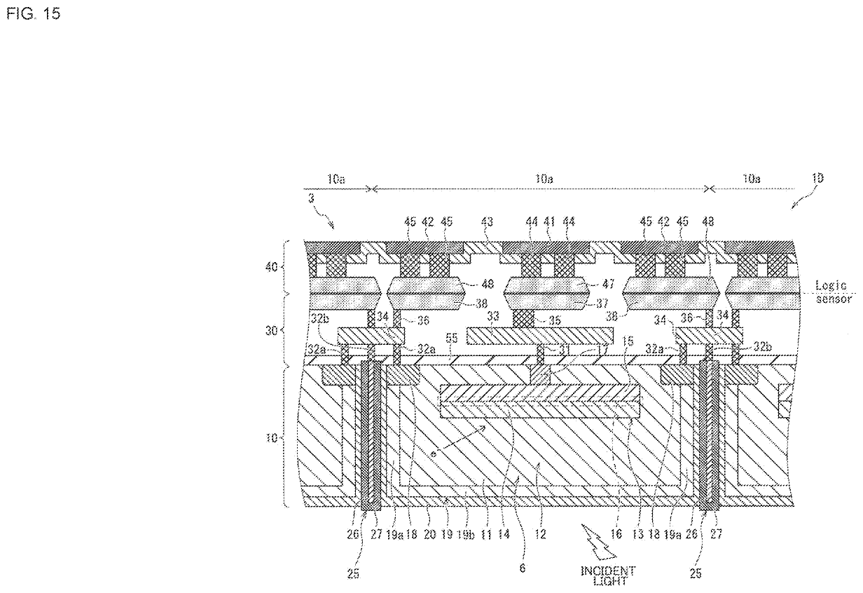

That is, as shown in FIGS. 14 and 15, the pixel 3 of the fifth embodiment includes a reflective film 55 in place of the first reflective film 51 and the second reflective film 52 of the third embodiment. The reflective film 55 is formed of an insulating film having the highest reflectance among the interlayer insulating films in the sensor-side wiring layer 30, for example, such as a silicon nitride (SixNy) film or a silicon oxide film.

The reflective film 55 is provided on the first surface of the sensor substrate 10 in contact with the first surface so as to cover the entire surface of the pixel forming region 10a of the sensor substrate 10.

In this fifth embodiment, the contact electrode 31 penetrates the reflective film 55 and is electrically connected to the n-type first contact region 17. The contact electrode 32a penetrates the reflective film 55 and is electrically connected to the p-type second contact region 18. The contact electrode 32b penetrates the reflective film 55 and is electrically connected to the metal film 26 of the inter-pixel separation region 25.

In the distance image sensor 1D according to the fifth embodiment, the reflective film 55 of the pixel 3 covers the first surface side of the pixel forming region 10a of the sensor substrate 10 as described above. Therefore, according to the distance image sensor 1D of the fifth embodiment, since the light incident from the second surface of the sensor substrate 10 and having passed through the APD element 6 is reflected by the reflective film 55 and returns to the APD element 6, it is possible to improve the quantum efficiency of the APD element 6 due to the reflection effect of the reflective film 55. Since the reflective film 55 is formed of an insulating film, no parasitic capacitance is added between the p-type well region 11 of the sensor substrate 10 and the reflective film 55, and the overall cathode capacitance can be reduced. As a result, the quenching operation (Dead Time) of the APD element 6 can be shortened, and the time resolution can be improved. That is, in the distance image sensor 1D according to the fifth embodiment, it is also possible to improve the quantum efficiency and the time resolution.

Since the reflective film 55 is formed of an insulating film, the reflective film 55 can be provided on the entire first surface of the sensor substrate 10, and a short circuit between the contact electrode 31 and the contact electrode 32a, that is, between the cathode and the anode, can be suppressed.

In this fifth embodiment, similarly to the above-described modified example, with reference to FIG. 8, the n-type first contact region 17 may be arranged in the n-type second electrode region 15.

### Configuration Example of Electronic Apparatus

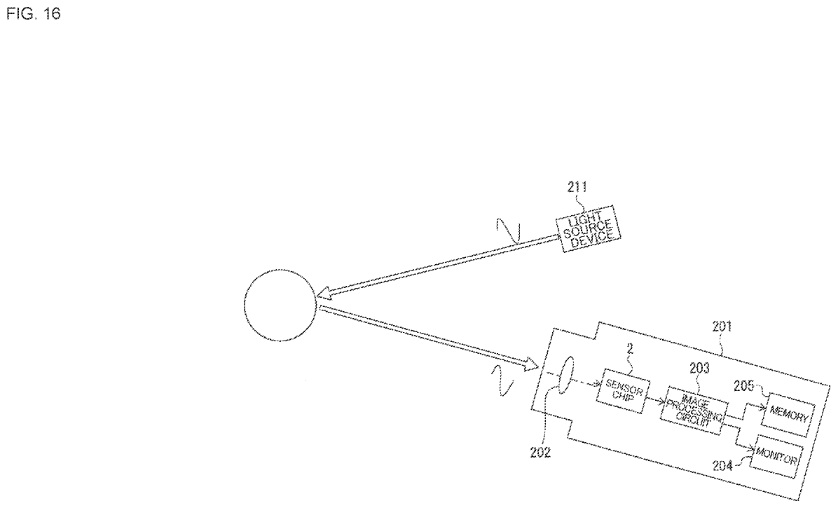

As shown in FIG. 16, a distance image apparatus 201 as an electronic apparatus includes an optical system 202, a sensor chip 2, an image processing circuit 203, a monitor 204, and a memory 205. The distance image apparatus 201 can acquire a distance image according to the distance to the subject by receiving light (modulated light or pulsed light) that has been projected from a light source device 211 toward the subject and reflected on the surface of the subject.

The optical system 202 is configured to have one or a plurality of lenses, and guides the image light (incident light) from the subject to the sensor chip 2 and forms an image on the light receiving surface (sensor portion) of the sensor chip 2.

The sensor chip 2 of each of the above-described embodiments is used as the sensor chip 2, and a distance signal indicating a distance obtained from the light receiving signal (APD OUT) output from the sensor chip 2 is supplied to the image processing circuit 203.

The image processing circuit 203 performs image processing for constructing a distance image based on the distance signal supplied from the sensor chip 2, and the distance image (image data) obtained by the image processing is supplied to the monitor 204 and displayed, or is supplied to the memory 205 and stored (recorded).

In the distance image apparatus 201 configured in this way, using the sensor chip 2 described above, the distance to the subject can be calculated based only on the light receiving signals from the highly stable pixels 3, and the distance image can be generated with high accuracy. That is, the distance image apparatus 201 can acquire a more accurate distance image.

### Usage Example of Image Sensor

The above-mentioned sensor chip 2 (image sensor) can be used in various cases for sensing light such as visible light, infrared light, ultraviolet light, and X-ray, as described below.
Devices that capture images used for viewing, such as digital cameras and mobile apparatuses with camera functions
Devices used for transportation, such as in-vehicle sensors that capture front, rear, surrounding, and interior view images of automobiles, monitoring cameras that monitor traveling vehicles and roads, ranging sensors that measure a distance between vehicles, and the like, for safe driving such as automatic stop, recognition of a driver's condition, and the like
Devices used for home appliances such as TVs, refrigerators, and air conditioners in order to photograph a user's gesture and perform device operations in accordance with the gesture
Devices used for medical treatment and healthcare, such as endoscopes and devices that perform angiography by receiving infrared light
Devices used for security, such as monitoring cameras for crime prevention and cameras for personal authentication
Devices used for beauty, such as a skin measuring device that captures images of the skin and a microscope that captures images of the scalp
Devices used for sports, such as action cameras and wearable cameras for sports applications
Devices used for agriculture, such as cameras for monitoring conditions of fields and crops

The present technology can also be configured as follows.

(1) A semiconductor device including:

a pixel array portion in which a plurality of pixels are arranged in a matrix, each of the plurality of pixels including:
an avalanche photodiode element formed in a semiconductor layer; and
a first metal wiring provided on a first surface of the semiconductor layer, the avalanche photodiode element including:
   a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
   a first contact region of the second conductivity type which is provided in contact with the second electrode region between the first surface of the semiconductor layer and the second electrode region, and of which the contour is located inside a contour of the second electrode region in a plan view, and
   the first metal wiring being electrically connected to the first contact region, and a contour thereof being located between the contour of the second electrode region and the contour of the first contact region in a plan view.

(2) The semiconductor device according to (1), wherein the contour of the first metal wiring is flush with the contour of the second electrode region in a plan view.

(3) The semiconductor device according to (1) or (2), wherein the avalanche photodiode element further includes a second contact region of the first conductivity type provided on the first surface side of the semiconductor layer so as to be electrically connected to the first electrode region, the pixel further includes a second metal wiring provided on the first surface of the semiconductor layer so as to be electrically connected to the second contact region, and

a contour of the second metal wiring is located between the contour of the second electrode region and the contour of the second contact region in a plan view.

(4) A semiconductor device including: a pixel array portion in which a plurality of pixels are arranged in a matrix, each of the plurality of pixels including:
an avalanche photodiode element formed in a semiconductor layer; and
a first conductive reflective film provided on a first surface of the semiconductor layer, the avalanche photodiode element including:
   a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
   a first contact region of the second conductivity type which is provided in contact with the second electrode region between the first surface of the semiconductor layer and the second electrode region, and of which the contour is located inside a contour of the second electrode region in a plan view, and the first reflective film being electrically connected to the first contact region, and
   a contour thereof being located between the contour of the second electrode region and the contour of the first contact region in a plan view.

(5) The semiconductor device according to (4), wherein the contour of the first reflective film is flush with the contour of the second electrode region in a plan view.

(6) The semiconductor device according to (4) or (5), wherein the avalanche photodiode element further includes a second contact region of the first conductivity type provided on the first surface side of the semiconductor layer so as to be electrically connected to the first electrode region, the pixel further includes a second reflective film provided on the first surface of the semiconductor layer so as to be electrically connected to the second contact region, and

a contour of the second reflective film is located between the contour of the second electrode region and the contour of the second contact region in a plan view.

(7) A semiconductor device including:
a pixel array portion in which a plurality of pixels are arranged in a matrix, each of the plurality of pixels including:
   an avalanche photodiode element formed in a semiconductor layer; and
   an insulating reflective film provided on a first surface of the semiconductor layer, the avalanche photodiode element including:
      a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
a first contact region of the second conductivity type which is provided in contact with the second electrode region between the first surface of the semiconductor layer and the second electrode region, and of which the contour is located inside a contour of the second electrode region in a plan view, and the reflective film covering an entire surface of the semiconductor layer on the pixel forming region.
(8) The semiconductor device according to any one of (1) to (7), wherein the first contact region is provided on the second electrode region so as to be in contact with an upper portion of the second electrode region.
(9) The semiconductor device according to any one of (1) to (7), wherein the first contact region is provided in an upper portion of the second electrode region.
(10) An electronic apparatus including the semiconductor device according to any one of (1) to (9) and an optical system that forms an image of image light from a subject on a second surface opposite to the first surface of the semiconductor layer.

It is to be noted that the scope of the present invention is not limited to the embodiments illustrated and described, but includes all embodiments that can bring the equivalent advantageous effects aimed by the present invention. Furthermore, the scope of the present invention is not limited to the combinations of the features of the present invention defined by the claims, but can be defined by specific and desired combinations of each of the features disclosed herein.

### REFERENCE SIGNS LIST

1, 1B, 1C, 1D Distance image sensor (semiconductor device)
2 Sensor chip
2A Pixel array portion
2B Peripheral region
2C Pad region
3 Pixel
4 Electrode pad
5 Bias voltage application portion
6 APD element
7 Quenching resistance element
8 Inverter
10 Sensor substrate
10a Pixel forming region
11 p-type well region
12 Light absorbing portion
13 Multiplication portion
14 p-type first electrode region
15 n-type second electrode region
16 Avalanche multiplication region
17 n-type first contact region
18 p-type second contact region
19 p-type charge storage region
20 p-type pinning region
30 Sensor-side wiring layer
31, 32a, 32b Contact electrode
33 First metal wiring
34 Second metal wiring
35, 36a, 36b Contact electrode
37, 38 Metal pad
40 Logic-side wiring layer
41, 42 Electrode pad
43 Insulating layer
44, 45 Contact electrode
47, 48 Metal pad
51 First reflective film
52 Second reflective film
53 Insulating film
55 Reflective film

1. A semiconductor device comprising:
a pixel array portion in which a plurality of pixels are arranged in a matrix, each of the plurality of pixels including:
an avalanche photodiode element formed in a semiconductor layer; and
a first metal wiring provided on a first surface of the semiconductor layer, the avalanche photodiode element including:
a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
a first contact region of the second conductivity type which is provided in contact with the second electrode region between the first surface of the semiconductor layer and the second electrode region, and of which the contour is located inside a contour of the second electrode region in a plan view, and
the first metal wiring being electrically connected to the first contact region, and a contour thereof being located between the contour of the second electrode region and the contour of the first contact region in a plan view.

2. The semiconductor device according to claim 1, wherein the contour of the first metal wiring is flush with the contour of the second electrode region in a plan view.

3. The semiconductor device according to claim 1, wherein
the avalanche photodiode element further includes a second contact region of the first conductivity type provided on the first surface side of the semiconductor layer so as to be electrically connected to the first electrode region, the pixel further includes a second metal wiring provided on the first surface of the semiconductor layer so as to be electrically connected to the second contact region, and
a contour of the second metal wiring is located between the contour of the second electrode region and the contour of the second contact region in a plan view.

4. The semiconductor device according to claim 1, wherein the first contact region is provided on the second electrode region so as to be in contact with an upper portion of the second electrode region.

5. The semiconductor device according to claim 1, wherein the first contact region is provided in an upper portion of the second electrode region.

6. An electronic apparatus comprising:
a semiconductor device including:
a pixel array portion in which a plurality of pixels are arranged in a matrix, each of the plurality of pixels including:
an avalanche photodiode element formed in a semiconductor layer; and
a first metal wiring provided on a first surface of the semiconductor layer, the avalanche photodiode element including:
a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
a first contact region of the second conductivity type which is provided in contact with the second electrode region between the first surface of the semiconductor layer and the second electrode region, and of which the contour is located inside a contour of the second electrode region in a plan view, and
the first metal wiring being electrically connected to the first contact region, and a contour thereof being located between the contour of the second electrode region and the contour of the first contact region in a plan view; and
an optical system that forms an image of image light from a subject on a second surface opposite to the first surface of the semiconductor layer.

7. A semiconductor device comprising:
a pixel array portion in which a plurality of pixels are arranged in a matrix, each of the plurality of pixels including:
an avalanche photodiode element formed in a semiconductor layer; and
a first conductive reflective film provided on a first surface of the semiconductor layer, the avalanche photodiode element including:
a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
a first contact region of the second conductivity type which is provided in contact with the second electrode region between the first surface of the semiconductor layer and the second electrode region, and of which the contour is located inside a contour of the second electrode region in a plan view, and
the first reflective film being electrically connected to the first contact region, and a contour thereof being located between the contour of the second electrode region and the contour of the first contact region in a plan view.

8. The semiconductor device according to claim 7, wherein the contour of the first reflective film is flush with the contour of the second electrode region in a plan view.

9. The semiconductor device according to claim 7, wherein
the avalanche photodiode element further includes a second contact region of the first conductivity type provided on the first surface side of the semiconductor layer so as to be electrically connected to the first electrode region,
the pixel further includes a second reflective film provided on the first surface of the semiconductor layer so as to be electrically connected to the second contact region, and
a contour of the second reflective film is located between the contour of the second electrode region and the contour of the second contact region in a plan view.

10. The semiconductor device according to claim 7, wherein the first contact region is provided on the second electrode region so as to be in contact with an upper portion of the second electrode region.

11. The semiconductor device according to claim 7, wherein the first contact region is provided in an upper portion of the second electrode region.

12. A semiconductor device comprising:
a pixel array portion in which a plurality of pixels are arranged in a matrix, each of the plurality of pixels including:
an avalanche photodiode element formed in a semiconductor layer; and
an insulating reflective film provided on a first surface of the semiconductor layer, the avalanche photodiode element including:
a multiplication portion which includes a first electrode region of a first conductivity type provided on the first surface side of the semiconductor layer and a second electrode region of a second conductivity type provided at a position shallower than the first electrode region to form a pn junction with the first electrode region, and in which an avalanche multiplication region is formed at an interface of the pn junction; and
a first contact region of the second conductivity type which is provided in contact with the second electrode region between the first surface of the semiconductor layer and the second electrode region, and of which the contour is located inside a contour of the second electrode region in a plan view, and
the reflective film covering an entire surface of the semiconductor layer on the pixel forming region.

13. The semiconductor device according to claim 12, wherein the first contact region is provided on the second electrode region so as to be in contact with an upper portion of the second electrode region.

14. The semiconductor device according to claim 12, wherein the first contact region is provided in an upper portion of the second electrode region.
